(19) United States
(12) Patent Application Publication
(10) Pub. No.: US 2016/0204338 A1
(43) Pub. Date: Jul. 14, 2016

(54) METHOD AND DEVICE FOR PRODUCING AN ELASTOMER STACK ACTUATOR

(71) Applicant: PARKER-HANNIFIN CORPORATION, Cleveland, OH (US)

(72) Inventors: Holger Schmeer, Köln (DE); Torsten Feller, Wuppertal (DE); Nicolas Degiorgio, Krefeld (DE); Karin Clauberg, Solingen (DE); Stephan Nowak, Köln (DE)

(21) Appl. No.: 14/892,762

(22) PCT Filed: May 23, 2014
(86) PCT No.: PCT/EP2014/060705

§ 371 Date: Feb. 16, 2016

(30) Foreign Application Priority Data
May 23, 2013 (EP) 13168855.8
Jun. 7, 2013 (EP) 13170988.3

(51) Int. Cl. H01L 41/27; H01L 41/293; H01L 41/23; H01L 41/053; H01L 41/193; H01L 41/047; H01L 41/45

(52) U.S. Cl. CPC H01L 41/27; H01L 41/0474; H01L 41/293; H01L 41/45; H01L 41/053; H01L 41/193; H01L 41/23

(57) ABSTRACT

A method for producing an elastomer-based film stack actuator may include: a starting process of: providing an elastomer film having an elastomer layer and two cover layers, and removing one of the two cover layers to produce a delaminated film; a stacking process, of: applying a layer of electrodes to the elastomer layer of the delaminated film assembly, laminating an additional delaminated elastomer film on the film assembly having electrodes, and removing one of the two cover layers from the laminated film assembly to produce a delaminated film assembly; and a finalization process of: contacting the electrodes of the film assembly produced by the stacking process, separating the stacking actuators of the film assembly produced by the stacking process, and encapsulating the separated stacking actuators. The stacking process steps may be repeated by using the delaminated film assembly of the final step in the initial step.

### CROSS-REFERENCE TO RELATED APPLICATIONS

The present application is a U.S. national phase application filed under 35 U.S.C. §371 of International Patent Application Serial No. PCT/EP2014/060705 entitled “METHOD AND DEVICE FOR PRODUCING AN ELASTOMER STACK ACTUATOR,” and filed May 23, 2014, which application claims priority to the filing dates of European Patent Application No. 13170988.3, filed Jun. 7, 2013 and European Patent Application No. 13168855.8, filed May 23, 2013 the disclosures of which applications are herein incorporated by reference.

### BACKGROUND

The invention relates to a method for producing an elastomer-based film stack actuator comprising a start process, a stacking process and a finalizing process. Moreover, the invention relates to a film stack actuator produced by the method and a device for manufacturing an elastomer-based film stack actuator.

Plastic composite materials are employed in a variety of applications. For example, a suitable laminate composite is used as a packaging material, insulation material or as a construction material. In addition to this conventional application, laminate (layer) composites are increasingly used as active components in generator applications, sensor applications or actuator applications.

Thus it is already known that an electro-active material such as a dielectric elastomer, interposed between two electrodes, is able to produce an actuator and/or a sensor. As electroactive polymers are referred to polymers based on an electrical stimulation able to change their physical properties. The structure of the actuators corresponds to a plate capacitor. Actuators are thus formed from at least a resilient dielectric and two flexible, preferably parallel and oppositely arranged, electrodes. If a voltage is applied to the electrically conductive electrodes, the electric field generated by the voltage will cause a contraction of the dielectric in the field direction and at the same time an increase in the actuator area perpendicular to the field direction.

As any electromechanical transducer or actuator, a dielectric polymer actuator can also be operated as a sensor. This is done via the measurable electrical capacitance change under the influence of a mechanical force, which causes a deformation of the actuator or sensor.

Generally it can be stated that dielectric elastomers with the highest possible field strength (close to the breakdown field strength of the dielectric) can/should be operated. The operating voltage of the actuators in this case depends on the layer thickness of the dielectric. This can lie, for example, between 100 V and 20 kV, or, for example, in the range of 600 V. This allows very high energy densities and low response times, which may be in the millisecond range or less. The mechanical behavior of the dielectric elastomer actuators is also dependent on the operating voltage. Since a low operating voltage is desirable, it is a constant concern to reduce the thickness of the dielectric elastomer film.

One way to increase the actuator forces or the capacitance of the dielectric elastomers is to stack the actuators on top of each other. The stacked individual actuators can be electrically connected in parallel. Due to the parallel connection of the individual actuators, the electrode area, that is the active surface, becomes multiplied, and thus is multiplied also the maximum achievable mechanical feedback. So it is conceivable, for example, to stack between 40 and 400 individual actuators one above the other, to produce a so-called stack actuator. A stack actuator is therefore characterized by the fact that a plurality of individual actuators are stacked on top of each other and preferably connected in parallel.

However, the production of stack actuators is difficult. Basically, under the current technological progress, just two process types are known, respectively the wet and the dry deposition of the materials used. While in wet deposition, the respective layers are applied as a liquid film and thus can react with each other, in the dry deposition method, the individual film layers are laminated sequential, on each other.

In EP2 136 419 A2, a monolithic multi-layer actuator or a stack actuator as well as a wet-deposition processes are described for producing a monolithic multilayer actuator. The individual layers are linked together. The individual materials are adjusted to each other such that they react with each other due to a chemical reaction concatenation. An advantage in the described wet-deposition process is the avoidance of delamination effects of the individual layers. However, the method is barely suitable for an automatic and efficient production of a plurality of stack actuators.

In a dry deposition method, a plurality of elastomer layers are stacked one above the other, mainly a film provided with electrodes is laminated on another film. Elastomer layers, in particular layers of polyurethane, are particularly suitable for electroactive applications. On the produced film assembly, another layer with electrodes can then applied and another film may be laminated, etc. A problem with the dry-deposition processes known from the prior state of technology stands especially in the handling of particularly thin layers of elastomer, such as polyurethane films, whose size is in the range between about 10 microns and about 200 microns. In addition to the small thickness, the processing is difficult especially because of the sticky properties of the polyurethane layers. Furthermore, in the simultaneous production of a plurality of stack actuators, the exact positioning of various layers and/or electrodes is problematic.

Overall, no method or device for making a film stack actuator is currently known from the prior state of technology, one which allows an efficient production which can be in particular fit to be used for an industrial production.

### SUMMARY

Therefore, the present invention has the object to provide a method for producing an elastomer-based film stack actuator and a device able to provide the manufacturing an elastomer-based film stack actuator which efficiently enables the production of film stack actuators.

The previously derived and indicated task is achieved according to a first aspect of the invention in a method according to patent claim 1. The method for manufacturing an elastomer-based film stack actuator, in particular a polyurethane-based film stack actuator, consists of:

a) a starting process having the steps:

a1) providing an elastomer layer and two cover layers in a form of a lamination layer and a liner layer, and

a2) removing of one of the two cover layers from the elastomer film to produce a delaminated film assembly

b) a stacking process following the start process, having the steps:

b1) applying a layer of electrodes to the elastomer layer of the delaminated film assembly,

b2) lamination an additional delaminated elastomer film on the film assembly having electrodes, and

b3) removing of one of the two cover layers from the laminated film assembly to produce a delaminated film assembly

wherein, in the stacking process b) the steps b1) to b3) are repeated at least once, and wherein the delaminated film assembly produces in the previous step b3) is provided to the repeated step b1) as a delaminated film assembly,

c) a finalization process following the stacking process, having the steps:

c1) contacting the electrodes of the film assembly produced by the stacking process,

c2) separating the stack actuators of the film assembly produced by the stacking process, and

c3) encapsulating the separated stacking actuators.

In contrast to the prior state of technology, which always has at least one covering layer in the form of a liner layer or a laminated layer for the processing of the film or of the film assembly during the stacking process, an efficient manufacturing method can be provided. In particular, sticky and particularly thin elastomer layers (sized mainly <200 micrometers) can be processed in an efficient manner.

The inventive dry deposition method mainly consists of three processes: a start-up process, a stacking process and a finalizing process.

In the starting process an elastomer film is provided. For example, an elastomer film with predetermined dimensions can be provided in particular in the form of an elastomer-based film sheet. The dimensions are dependent, in particular, on the processing units used or on the machine. The elastomer film consists of an elastomer layer and two cover layers, a laminated layer and a liner layer. The elastomer layer, which in particular may have a thickness of about 10 microns to 200 microns, may be set between the laminated layer, or a polyethylene layer (PE-layer), and the liner layer, like a paper liner layer. In other words, the two surfaces of the elastomer layer, which is particularly sticky, are provided with cover layers.

An elastomer film may preferably be made of a material selected to be from the group of polyurethane elastomers, silicone elastomers and/or acrylate elastomers. More particularly, the elastomer layer may be selected from the group comprising polyurethane elastomers, silicone elastomers, and/or acrylate elastomers. It is particularly preferably that the elastomer film shall be made of a polyurethane film (PU film) with a polyurethane layer (PU layer) and two cover layers.

An elastomer shall always be underlaid with a dielectric elastomer, similarly as a dielectric elastomer film, a dielectric elastomer layer or a dielectric elastomer based film stack actuator.

In preparation of the stack process following the start process, the elastomer film shall be delaminated. Preferably, the laminated layer will be removed. By removing only one of the two cover layers, the elastomer film may be easily processed further in the subsequent processing steps. Thus, for example, the delaminated elastomer film can be fed on, for example by means of rollers, through the preferably still existing liner layer, and transferred to subsequent processing stations.

The delaminated elastomer film is further processed in the stack process, as follows. First, a layer with electrodes may be applied to the surface of the dselaminated elastomer film, i.e. to the elastomer layer. In particular, a plurality of electrodes can be applied to enable parallel production of a plurality of stack actuators.

In a subsequent laminating step, a new delaminated elastomer film is further applied to the elastomer layer previously provided with the electrode layer. In particular, the additional elastomer film has an elastomer layer and, as cover layer, a liner layer. The additional elastomer film is laminated in such a way that the elastomer layer directly contacts the electrode layer. The result of this lamination is particularly an assembly comprising a lower cover layer, preferably in the form of liner layer, an elastomer layer disposed thereon, a electrode layer disposed thereon, a elastomer layer disposed thereon, and a cover layer disposed thereon, preferably in the form of a liner layer.

In the delaminating step following the lamination step, one of the two cover layers, e.g. the liner layer, will be removed, while the other cover layer, e.g. the liner layer, remains on the laminated and delaminated film assembly. In other words, an elastomer layer of the film assembly is exposed after performing the delamination. By removing only one of the two cover layers, the elastomer assembly may be easily processed further in the subsequent processing steps.

The delaminated film assembly is then preferably used as the starting material for the repeating of steps b1) to b3). In other words, a further electrode layer is preferably applied to the exposed PU layer, on the electrode layer, then another delaminated elastomer film will be laminated and then a (exactly one) cover layer of the laminated film assembly having now two electrode layers and three elastomer layers will be removed. The steps b1) to b3) are preferably repeated so often until a stack actuator reaches the desired number of individual actuators stacked one above the other (for example, 10 to 1000). After the film assembly has been set up with the desired number of stacked individual actuators, the film assembly produced can be fed to the finalization step b3).

In the finalization step, the electrodes can be contacted and the stack actuators are separated. It may be the case that initially the electrodes can be contacted and only then the stack actuators are separated or stack actuators are initially separated and only then the electrodes of the separated stack actuators are contacted. In particular, the individual actuators of a stack actuator can be connected in parallel.

In a further step, the separated stack actuators are particularly encapsulated, especially to protect them against unwanted environmental influences. In an effective manner, a plurality of actuators in the stack can be essentially produced in parallel.

In a first embodiment of the inventive method, the elastomer film can be cut in the step a3) of the start-up process a). For example, a elastomer foil sheet can be produced by a cutting station with predetermined dimensions. If preferred, the elastomer film may be cut before removing a cover layer, e.g. the laminated layer. If, in an alternative variant of the invention, the elastomer film is cut only after removing the laminated layer, it must be ensured that the elastomer layer remains free of dust or other particles.

Moreover, the application of the electrodes on the elastomer layer can be made, preferably, of a deposition of patterned electrodes. The patterned electrodes can be applied by a screen printing process, a gravure printing process, a flexographic and/or a spraying method. In a simple process, and particularly with precise positioning, an electrode layer can be applied with a plurality of electrodes on the elastomer layer. A structured or segmented layer can be formed. Further, an electrode may also be formed, according to a preferred embodiment, of a material which is selected from the group consisting of metals, metal alloys, conductive oligopolymers or polymers, conductive oxides, and carbons, and/or filled with conductive polymer based fillers.

According to a further preferred embodiment, the electrodes can be applied in alternating steps b1), in each case with an offset of between 0.2 mm and 2.0 mm. In order to make the contacting process, in a subsequent contacting step, simpler, the electrodes are applied in alternating steps b1) with an offset. Using the offset, a terminal contact area may be generated, in particular, for each electrode. In a simple manner, the stacked actuators can be connected in parallel, in a subsequent contacting step.

The realization of the contact between the plurality of electrodes of an actuator can generally be made in an arbitrary manner. According to a preferred embodiment, the realization of the contact between electrodes may be made by the generation of cavities on or at the terminal contact areas of the electrodes. For example, the cavities may be produced by a punching and/or a cutting process. The cavities generated as such can be filled with a conductive paste, to achieve the contact between the electrode. In particular, this contacting process can be carried out before the separation of the actuators. For example, the cavities can be produced in parallel for all stack actuators of a PU foil sheet. This way, a further improvement of the efficiency of the manufacturing process is achieved.

In the event that a conductive paste is used for realization of contacts, it is preferred, according to a further embodiment, to be of the same material as the stack actuator when the conductive paste is formed at least of a chemically similar material as the stack actuator. When the contacting mass material, the contacting mass can enter into a monolithic connection with the stack actuator. Especially the life of the contacting it can be thus significantly increased.

In an alternative and preferred embodiment, the stack actuators can be separated, so that the end faces of the terminal contact surfaces of the electrodes become exposed. An electrical conductor can be attached to the exposed contact area of the electrodes, to achieve the contact. In other words, the stack actuators are initially separated, in this type of contact. As it will be explained below, the ultrasound cutting is particularly suitable for separating. The stack actuators are separated in a manner than enables the end faces of the electrodes, such as the end faces of the terminal contact areas of the electrodes, are exposed. The individual electrodes of an actuator are then provided with ladders to contact the exposed end faces of the electrode. The exposed ends can be contacted, in a preferred embodiment of the invention, by means of a screen printing process. In particular, an electrical conductor for contacting the exposed ends of the electrodes is applied by a screen printing process.

In a particularly preferred embodiment of the invention, the electrical conductors are moulded by a casting process. For example, the occasional stack actuator can be placed in a mould. In this way, the contacting of the electrodes can be produced in a particularly simpler and safer manner. The generation of cavities and their filling with a conductive paste may be omitted. Preferably, the filling of cavities can take place by means of a casting process. The film sheet having a plurality of stack actuators with cavities can be, for this example, used in the mould.

As already described, it is proposed according to a preferred embodiment of the invention, that the separation of the actuators is carried out by means of an ultrasound process. Although it is conceivable in principle, to be made using other techniques, such as laser cutting, vibration, cutting and/or stamping. However, it has been recognized that particularly clean cut edges will be achieved by using a ultrasound cutting method. If clean cut edges are produced, the electrodes can be exposed so that they can be contacted safely and easily. Preferably also the cutting of the elastomer film can be carried out by means of an ultrasound cutting process.

Moreover, according to a further embodiment of the invention, the separated actuators can be encapsulated by pouring with a particularly low modulus of elasticity type of material, in particular silicone or polyurethane. By encapsulation, the stack actuator can be protected from external influences. A silicone has better moisture-repelling properties as a PU. The advantage of PU is, in particular, that the PU encapsulation can enter into a monolithic connection with the stack actuator, as long as PU it is used as the elastomer. This has the consequence that it will only lead to minor losses in the transmission of force. The used material has further, preferably, a very low modulus of elasticity, not impeding the deflection of the actuator.

The encapsulation can be carried out, in principle, in an arbitrary manner. According to a preferred embodiment of the invention, the encapsulation of the stack actuators is carried out by using a mould. The mould tool can be filled by means of a 2K dosing system. In a particularly simple manner, a good encapsulation can be achieved. In particular, a mould tool can be used, this way allowing for a parallel encapsulation of a plurality of stack actuators. The efficiency of the present process can be further increased.

Another aspect is the production of an elastomer-based, in particular, a polyurethane-based film stack actuator, prepared according to the previously described method.

A dielectric elastomer layer, in particular a polyurethane layer should preferably have a relatively high dielectric constant (e.g. 4 to 10 F·m−1). In addition, a dielectric elastomer layer should preferably have a low mechanical stiffness in order to allow movements. A dielectric elastomer layer can be used in particular for an actuator application. However, dielectric elastomer layers can be also used for sensor applications.

An electrode is formed by an electrically conductive layer. Preferably, a PU coating on both surfaces with a conductive layer can lead to a direct contact or coating. It is understood that the bottom or the top of the PU layer may be only partially or in sections coated with an electrically conductive layer. In particular, a structured or segmented layer can be formed.

Another aspect of the invention is a device according to claim 13. The device for manufacturing an elastomer-based film stack actuator, in particular a polyurethane-based film stack actuator, consists of: The start process assembly includes a first delaminating station adapted for removing a top layer of an already provided elastomer film, in order to produce a delaminated film assembly. The provided elastomer film consists of an elastomer layer and two cover layers in the form of laminated and of a liner layer. The device includes a stack process assembly following to a start process assembly. The stack process assembly consists of an application station adapted for applying a layer of electrodes on the elastomer layer of the delaminated film assembly. The stack process arrangement consists of a laminating station adapted for laminating another delaminated elastomer film on to the film assembly provided with electrodes. The stack process assembly includes a second delamination station adapted for the removal of one of the two cover layers of the laminated film assembly, in order to produce a delaminated film assembly. The stack process assembly is set up to allow the delaminated film assembly generated by the second delamination station to supply either the application station or a following finalization process assembly. The device consists of a finalization process assembly following to a stack process assembly. The finalization process assembly includes a contacting station adapted for realization of the contact between the electrodes of the delaminated film assembly generated by the second delamination station. The finalization process assembly includes a separation station adapted for separating the stack actuators of the delaminated film assembly generated by the second delamination station. The finalization process assembly includes an encapsulation station adapted for encapsulating the separated stack actuators.

The device is particularly arranged for carrying out the method described above.

In a first embodiment of the inventive device, start process assembly may consist of a cutting station adapted to cut the provided elastomer film or the delaminated film assembly. An elastomer foil sheet can be made ready in a simple manner, for example by means of an ultrasound cutting process or other cutting processes, with the suitable dimensions for the subsequent processing stations.

In addition, the inventive device can be provided, according to a preferred embodiment, in so that it has a contact station that has a contacting device to achieve the contact of the electrodes. The contacting device may include a sucking part that sucks the slug resulting from the generation of a cavity. The contacting device may include a leading portion arranged for dosing the conductive paste into the cavity formed. If the contacting device has a contacting station which allows the generation of cavities, for example by punching, the simultaneous suction of the slug and the subsequent filling with a conductive paste of the cavity produced, can be executed with a plurality of contacting steps, by the same tool, in an efficient manner.

### BRIEF DESCRIPTION OF THE DRAWINGS

There are now a variety of ways, the inventive method, the inventive stack actuator and the inventive design to further design and develop. Reference may be made, on the one hand, to the claims subordinated to the independent patent claims on the other hand to the description of embodiments in conjunction with the drawing. In the drawings it is shown:

FIG. 1 a schematic view of a flow chart or a device of an embodiment according to the present invention,

FIG. 2 a schematic cross-sectional view of an embodiment of a PU film,

FIG. 3 a schematic plan view of an embodiment example of a film arrangement with electrodes,

FIG. 4 a schematic view of an embodiment of the laminating station and the second delamination station,

FIG. 5 a schematic cross-sectional view of an embodiment example of a delaminated film assembly,

FIG. 6a a schematic plan view of a first embodiment of a stack actuator,

FIG. 6b a schematic cross-sectional view of the stack actuator shown in FIG. 6a,

FIG. 6c a schematic plan view of another embodiment example of a stack actuator,

FIG. 7 a schematic view of an embodiment example of a contact device, and

FIG. 8 a schematic view of an exemplary course forces in an encapsulated stack actuator.

### DETAILED DESCRIPTION

Hereinafter, similar reference numbers were used for similar elements. Further, in the subsequent preferred embodiments, is described the preparation of a PU-based film stack actuator using the PU films. It is understood that in place of PU also another elastomer material may be used as the elastomer material.

Hereinafter, similar reference numbers were used for similar elements. Further, in the subsequent preferred embodiments, is described the preparation of a PU-based film stack actuator using the PU films. It is understood that in place of PU also another elastomer material may be used as the elastomer material.

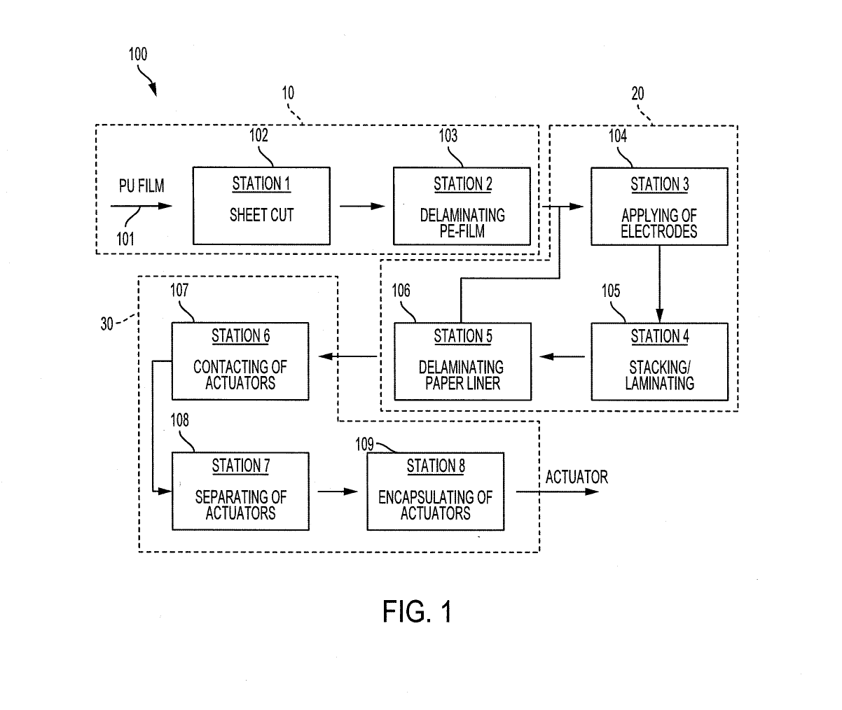

FIG. 1 shows a schematic view of a flow diagram 100 and an exemplary device 100 according to the present invention.

The device 100 includes a start process assembly 10, a stack process assembly 20 and a finalization process assembly 30.

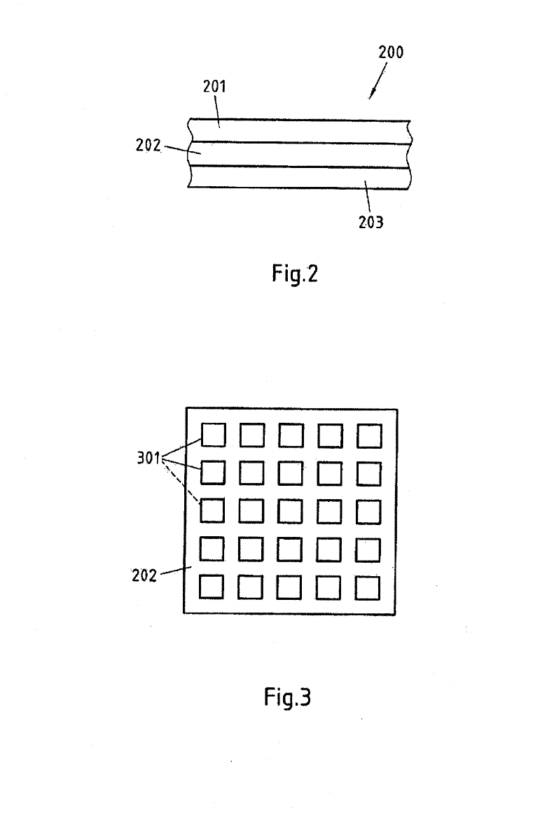

First, a polyurethane film 200 is provided in a first step 101. An exemplary and preferred embodiment of the provided polyurethane film 200 is illustrated in FIG. 2.

FIG. 2 shows a schematic sectional view of a polyurethane film 200. The polyurethane film 200 substantially contains three layers 201, 202, 203. The middle layer 202 is a polyurethane layer 202. Due to the high adhesive properties of this layer 202, the polyurethane film 200 is provided with two cover layers 201, 203 to simplify the further processing. To the polyurethane layer 202 is attached an upper cover layer 201 in form of a laminated layer 201, in particular a polyethylene layer 201 (PE-Schicht). Below the polyurethane layer 202 is another cover layer 203 in the form of a liner layer 203, arranged as a paper liner layer 203.

In the event that the polyurethane film 200 is not already having desired dimensions needed, the polyurethane film 200 can be cut to the desired dimensions in a step 102, using an arc cutting station 1 or a blank station 1. The particular continuously provided polyurethane film sheets 200 can be cut to the desired size, during an automated process.

The cut polyurethane film 200 or the cut polyurethane film sheet 200 can then be fed to a first delamination station 2. In a first delamination step 103, one of the two cover layers 201, 203, preferably the lamination layer 201, can be removed as a polyurethane layer (PE layer). If the PE layer 201 is removed before the sheet cutting step 102, it must be ensured that the elastomer layer or the polyurethane layer 202 remains free of dust and/or other particles. The paper must be separated in such a way that the paper fibers are avoided.

The delaminated polyurethane film 200, i.e. a film comprising the polyurethane layer 202 and a cover layer 203, by way of example in the form of a liner layer 203, especially of an application station 3, is supplied to the stack process assembly 20. In an electrode application step 104, at least one electrode 301, preferably a layer with a plurality of structured electrodes 301, is applied. The structured electrodes 301 are applied primarily in a screen printing process. Other processes are, in particular, conceivable for the accurate-positioning application of small structures. This might include gravure printing or flexographic printing, in particular, as well as a spraying process.

FIG. 3 shows a plan view of an execution example of a polyurethane layer 202 provided with electrodes 301 or a film arrangement. As is clearly shown, a variety of existing, square-formed electrodes 301 have been applied. As can be observed in FIG. 3, several stack actuators are produced simultaneously. The arrangement and the number of stack actuators or electrodes 301 may depend, in particular, on the size of the polyurethane film sheet 200. The stack actuators may be separated only after lamination step 105 in a separating station 7, explained in further detail below.

The polyurethane film 200 fitted with electrodes 301 is then supplied to a laminating station 4. The laminating station 4 is set up in for the purpose of performing a lamination step 105 or a stacking step 105. In particular, an additionally-provided, delaminated and, in particular, already-cut polyurethane film 401 is applied to the polyurethane film 200—which is fitted with electrodes—or to the film assembly. The additional polyurethane film 401 corresponds in its construction to the polyurethane film 200, already described in FIG. 2, with only just a cover layer, such as a liner layer.

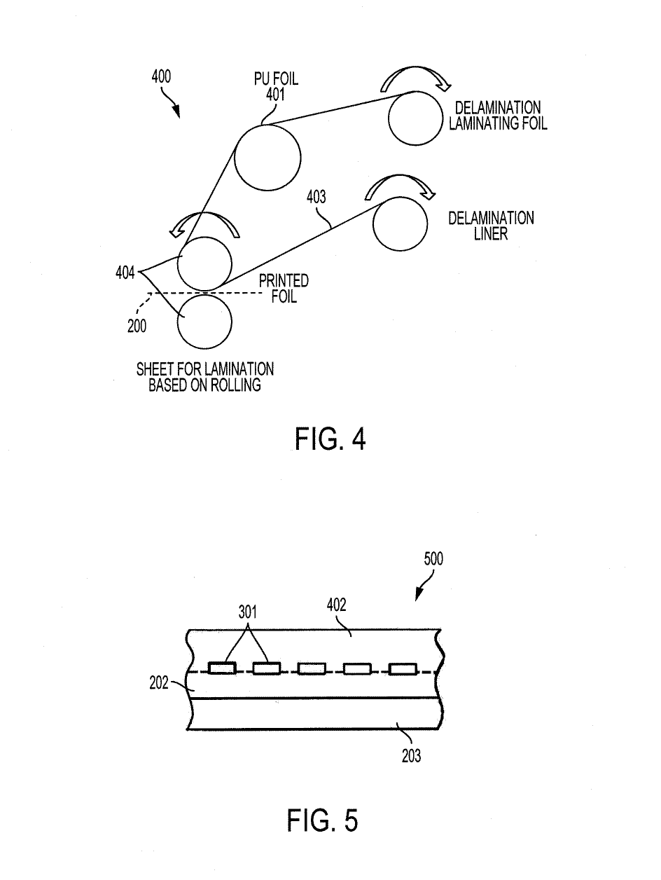

FIG. 4 shows a schematic view of an execution sample of a laminating station 400 according to the present invention. Prior to the lamination of the additional polyurethane film 401 on the printed polyurethane film 200 (by way of example) which is fitted with electrodes 301, the additional polyurethane film 401 is delaminated. In other words, the lamination layer of the polyurethane film 401 is removed in particular. It should be understood that, alternatively, the liner can be removed.

As has already been described, the laminating film or layer is withdrawn in this case from the PU elastomer 401 or PU layer prior to the lamination process. As can be seen from FIG. 4, the delaminated film 401 from the roll 404 or rolls 404 is laminated onto the sheet covered with electrodes. After the lamination process, the liner 403 or the liner layer 403 is delaminated in this case in an automatic process by the laminated sheet assembly (second delamination step 106 in the second delamination station 5).

In order to achieve a quasi-monolithic structure of the layers of a stack actuator, at this point there is the possibility of treating the surface of the printed sheet 200 by means of corona discharge, plasma discharge and/or electron irradiation.

An advantage of the present stacking process, or the present stacking process assembly 20, is that a high positioning accuracy can be ensured. The first film to be printed, also called the runner, which is provided from the start-up process assembly 10, serves as a basis of positioning for the additional electrode layers. That means that the positioning must be carried out in only one process step, in the printing step 104, because no accuracy is required in the lamination.

FIG. 5 shows a schematic cross-sectional view of an execution example of a delaminated film assembly 500 after the second delamination step 106. As can be seen in FIG. 5, the slide assembly 500 includes a lower cover layer 203 in the form of a liner layer 203, a polyurethane layer 202, an electrode layer 302 comprising a plurality of electrodes 301 and an additional polyurethane layer 402.

The layer assembly 500 can be supplied again to the application station 3, in order to apply an additional electrode layer above the additional polyurethane layer 402. In particular, steps 104, 105 and 106 can be repeated as often as needed in order to produce the desired number of layers or to stack the desired number, one above another, to individual actuators. In this context, it should be mentioned that the electrodes must be applied alternately for the presently described ‘reel to sheet lamination process’ 105. The offset may be between 0.2 and 2.0 mm.

After a layer assembly or film assembly has been produced with the desired number of stacked individual actuators or layers, this assembly of the finalization process assembly 30 is supplied. In the present execution example, the film assembly of the contact station 6 is supplied from the second delamination station 5. Contact station 6 is set up so as to provide the electrodes 301 with contacts in one contacting step 107. For example, it could be designed to generate cavities at the electrodes, particularly at the terminal contact surfaces of the electrodes.

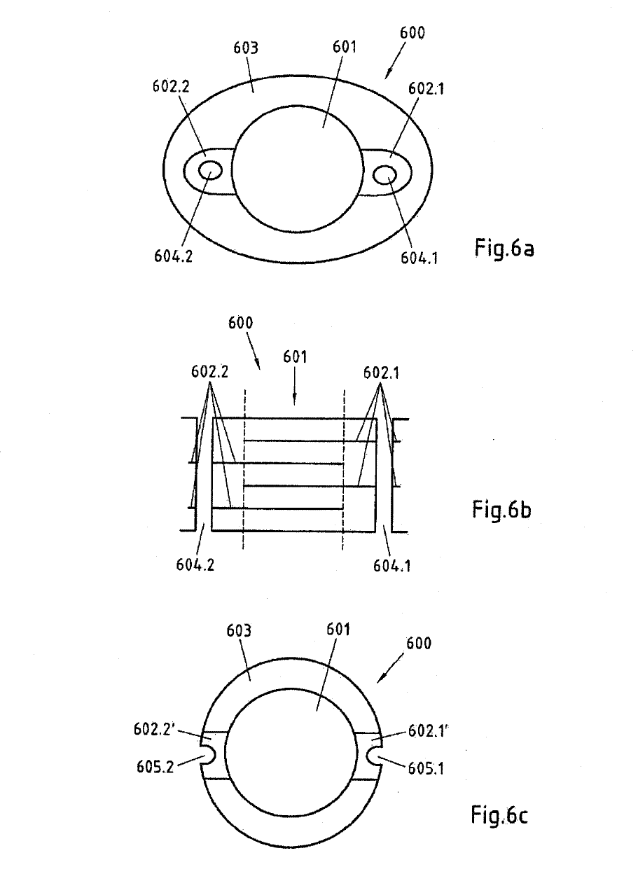

A sample plan view of a stacked actuator 600 with cavities 604.1, 604.2 is shown in FIG. 6a. As can be seen from the FIG. 6a, the stack actuator 600 in the center of the electrode 601 shows which [of these] are provided with terminal contact surfaces 602.1, 602.2. In particular, each electrode may be provided with a terminal contact surface 602.1, 602.2. A final contact surface and an electrode surface form a common conductive surface. For example, the connector contact surfaces 602.1, 602.2 can be made available with an offset through the alternating assembly of the electrodes previously described 601. Furthermore, the PU material is designated with a reference number 603. The terminal contact surfaces 602.1, 602.2 are each provided with a cavity 604.1, 604.2. This, for example, may have been created through a punching process.

A sectional view of the stacked actuator 600 is shown in FIG. 6b. The active surfaces 601 or electrodes 601 each show a terminal contact surface 602.1, 602.2. In particular, the assembly of the electrodes 601 with an offset can be seen. A cavity 604.1, 604.2 is respectively provided in the terminal contact surfaces 602.1, 602.2, which can be filled preferably with an electrically conductive paste. After filling, both the terminal contact surfaces 602.1 are connected with each other, as are the terminal contact surfaces 602.2.

As already described, the contacting of the electrodes can be carried out while the cavities 604.1, 604.2 in the stack actuator 600 are filled with conductive paste. The cavity 604.1, 604.2 can be prepared through a cutting process performable in the cutting station 7. Preferably, punching or ultrasonic cutting is to be used here. It should be understood that, in addition to a circular cross-section of a cavity, other geometric shapes are possible.

The cavity produced for the through-connection of the layers 604.1, 604.2 can be filled with the conductive paste by means of an automatic dispensing system, e.g. the company Vieweg. The stack actuators are located on the single sheet, so that the handling is simplified in the step. After all stack actuators are contacted, the entire sheet can be annealed so that the contacting paste is allowed to harden. The paste is preferably from the same or at least from a chemically similar material as the stack actuator itself, such that the contact mass can form a substantially monolithic connection with the stack actuator. Thus, the lifetime of the contact can be significantly increased.

Preferably, a dispensing unit 700 or a contact device 700, which penetrates the film or the stacked film assembly and fills the cavity upon pulling out the needle 700, can be used in this case (compare with FIG. 7). In this respect, the slug may be suctioned off via the suction unit 701, in particular during punching or puncturing, and subsequently the conductive paste can be dispensed through a supply unit 702, as through a supplementary supply line 702.

After the contacting of the electrodes, the sheet comprising a large number of stack actuators of a separating station 7 can be supplied.

The separating station 7 is set up such as to separate stack actuators in one separation step 108. The stack actuators can be separated from the individual sheets by means of a suitable cutting technique. Suitable cutting techniques may include ultrasonic, laser or vibration cutting as well as a punching process. Ultrasonic cutting is preferred because it has been recognized in accordance with the invention such that, in this way, good cutting edges and thus error-free parts can be achieved.

6c shows a further exemplary plan view of a stacked actuator 600′. An alternative contact option of the electrodes in particular is shown in FIG. 6c. So, in this case, the separating station 7 of the contact station 6 can be positioned in front. The separating station 7 can separate the stack actuators, by means of ultrasonic cutting in particular, such that the front edges of the electrodes 601, and the front surfaces of the terminal contact surfaces in particular 602.1 ‘, 602.2’ are exposed and can be contacted. For example, a groove 605.1, 605.2 can be filled with a conductive paste. It should be understood that the preparation of a groove 605.1, 605.2 can be dispensed with.

Preferably, the electrical contacts can be cast on. This type of contact has the advantage that a laborious production of cavities can be dispensed with.

After separating and contacting the stack actuators, the stack actuators of the encapsulation station 8 can be supplied. The encapsulation station 8 is set up so as to encapsulate the stack actuators in one encapsulation step 109.

In this step 109, the stack actuators are encapsulated. Possible materials, which can be used for the encapsulation, are silicone or polyurethane. Silicone has rather more moisture-repelling properties compared to PU, however PU can form a monolithic connection to the actuator, so it will only lead to minor losses in transmission of force. It is important in this case that the material used has a very low modulus of elasticity, so that the deflection of the actuator is not prevented. Another advantage of encapsulation is that the area of the inactive surface can be reduced. The above-mentioned materials exhibit insulating properties, so that there are no voltage flashovers. Additionally, the mechanical connection can be cast-in alongside directly.

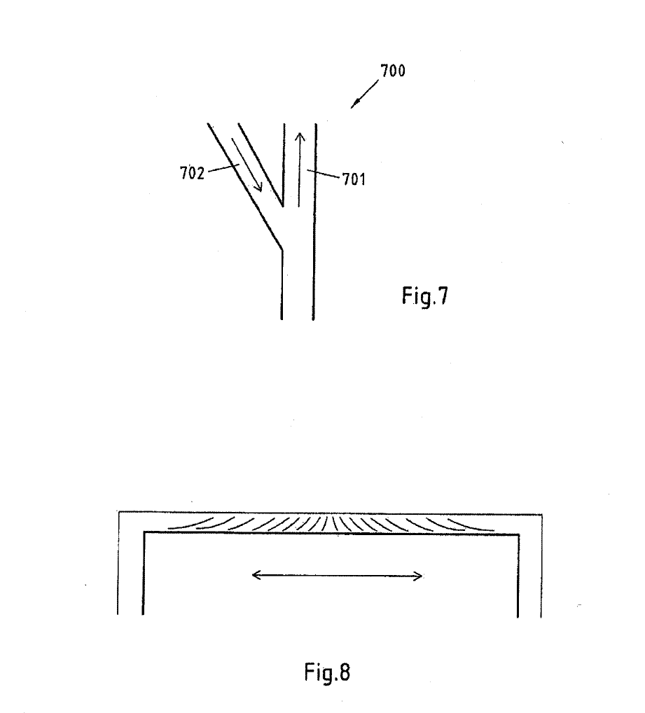

Another advantage of casting is the prevention of delamination of the stack actuator in the inactive border region. In the edge region, with an activated stack actuator and the associated expansion of the active actuator region, there may be voltages inhomogeneities—as can be observed in FIG. 8. Through casting, the individual film layers are held together, preventing delamination of the layers.

In addition, several stack actuators are encapsulated simultaneously in the process described here. Multiple stack actuators are positioned, for example, in one form. The form is filled with a 2K dispensing system, e.g. from the company Vieweg.

1. A method for producing an elastomer-based film stack actuator, including:
a) a start-up process comprising the steps of:
a1) providing an elastomer film with an elastomer layer, and two cover layers, in the form of a lamination layer and a liner layer, and
a2) removing one of the two cover layers from the elastomer film thereby producing a delaminated film assembly;
b) a stacking process following the start-up process, comprising the steps of:
b1) applying a layer of electrodes onto the elastomer layer of the delaminated film assembly;
b2) laminating a further delaminated elastomer film onto the film assembly provided with electrodes; and
b3) removing one of the two cover layers of the laminated film assembly for the production of a delaminated film assembly,
wherein steps b1) to b3) are repeated at least once in stacking process b),
wherein applying the layer of electrodes onto the elastomer layer comprises applying a layer of electrodes in successive, alternating steps b1), in each case with an offset of between 0.2 mm and 2.0 mm, and
wherein the delaminated film assembly created in the previous step b3) is provided as a delaminated film assembly for the repeated step b1).
c) a finalization process following the stacking process, comprising the steps of:
c1) contacting the electrodes of the film assembly generated by the stacking process; and
c2) separating one or more stack actuators from the film assembly generated by the stacking process.

2. The method according to claim 1, further comprising cutting the elastomer film in one step a3) of the start-up process a).

3. The method according to claim 1, wherein applying a layer of electrodes onto the elastomer layer comprises applying a layer of structured electrodes onto the elastomer layer via a screen printing process.

4. (canceled)

5. The method according to claim 1, wherein contacting the electrodes of the film assembly comprises creating cavities on or in one or more terminal contact surfaces of the electrodes, and filling the cavities with a conductive paste.

6. The method according to claim 5, wherein a material comprising the conductive paste is chemically similar to a material comprising the stack actuator, or is the same material comprising the stack actuator.

7. The method according to claim 1, further comprising separating one or more stack actuators from the film assembly so that the front surfaces the terminal contact surfaces of the electrodes are exposed, and attaching an electrical conductor for contacting the electrodes to the exposed terminal.

8. The method according to claim 7, further comprising casting the electrical conductor via a screen printing process.

9. The method according to claim 7, wherein separating the stack actuators comprises separating the stack actuators using an ultrasonic process, and/or cutting the elastomer sheet using an ultrasonic process.

10. The method according claim 1, further comprising encapsulating the separated stack actuators by casting with a material exhibiting a low modulus of elasticity, the material comprising silicone or polyurethane.

11. The method according to claim 1, further comprising encapsulating the stack actuators with an encapsulation form, which is filled by means of a two-component dispensing system.

12. An elastomer-based film stack actuator produced by a method according to claim 1.

13. An apparatus for producing an elastomer-based film stack actuator, the apparatus comprising:
a) a start-up process assembly comprising:
an initial delaminating station configured to remove a cover layer from an elastomer film thereby producing a delaminated film assembly, wherein the elastomer film comprises an elastomer layer and two cover layers in the form of a lamination layer and a liner layer;
b) a stack process assembly comprising:
an application station configured to apply a layer of electrodes onto the elastomer layer of the delaminated film assembly;
a lamination station configured to laminate an additional delaminated elastomer film onto the film assembly provided with the electrodes; and
a second delamination station configured to remove one of the two cover layers of the laminated film assembly thereby producing a delaminated film assembly,
wherein the stacking process assembly is configured to supply the delaminated film assembly generated by the second delamination station, either of the application station or a subsequent finalization process assembly; and
c) a finalization process assembly comprising:
a contacting station configured to contact the electrodes of the delaminated film assembly generated by the second delamination station;
a separating station configured to separate the stack actuators of the delaminated film assembly produced by the second delamination station; and
an encapsulation station configured to encapsulate the separated stack actuators.

14. The apparatus according to claim 13 wherein the starting-process assembly comprises a cutting station configured to cut the elastomer film or the delaminated film assembly.

15. The apparatus according to claim 13 wherein:
the contacting station has a contacting device for contacting the electrodes;
the contacting device comprises a suction unit configured to remove a slug generated during the production of a cavity; and
the contacting device has a supply unit adapted for dispensing a conductive paste into the cavity.

16. The method according to claim 2, wherein applying a layer of electrodes onto the elastomer layer comprises applying a layer of structured electrodes onto the elastomer layer via a screen printing process.

17. The apparatus according to claim 14 wherein:
the contacting station has a contacting device for contacting the electrodes;
the contacting device comprises a suction unit configured to remove a slug generated during the production of a cavity; and
the contacting device has a supply unit adapted for dispensing a conductive paste into the cavity.
